(19) United States
(12) Patent Application Publication
(10) Pub. No.: US 2011/0241227 A1
(43) Pub. Date: Oct. 6, 2011

(54) LIQUID RESIN COMPOSITION AND SEMICONDUCTOR DEVICE

(76) Inventor: Daisuke Oka, Tokyo (JP)

(21) Appl. No.: 13/133,249

(22) PCT Filed: Dec. 17, 2009
(86) PCT No.: PCT/JP2009/006981

§ 371 Date: Jun. 7, 2011

(30) Foreign Application Priority Data
Dec. 25, 2008 (JP) 2008-330760

(51) Int. Cl. H01L 23/29; C08L 63/00; C08K 5/3462; C08K 5/50

(52) U.S. Cl. 257/789; 523/400; 523/461; 523/451; 523/440; 257/E23.121

(57) ABSTRACT

The invention is aimed at providing a liquid resin composition capable of densely containing a filler and of filling up a narrow gap in a flip-chip-bonded semiconductor device, and a highly-reliable semiconductor device using the same. The liquid resin composition of the present invention contains (A) an epoxy resin; (B) an epoxy resin curing agent; and (C) a filler, wherein content of (C) the filler is 60% by weight or more and 80% by weight or less of the whole liquid resin composition, and contact angle (θ) of the liquid resin composition, measured at 110° C. in accordance with JIS R3257, is 30° or smaller.

### TECHNICAL FIELD

The present invention relates to a liquid resin composition and a semiconductor device.

### BACKGROUND ART

Flip-chip-bonded semiconductor device is configured by a semiconductor element and a substrate electrically connected with each other through solder bumps. In the flip-chip-bonded semiconductor device, a liquid resin composition called underfill material is filled between the semiconductor element and the substrate so as to reinforce the solder bumps and therearound, to thereby improve reliability of the connection. With recent trends of adoption of Low-K chips and lead-free solder bumps, the underfill material used in this sort of flip-chip package filled with the underfill has more strongly been desired to reduce thermal expansion, for the purpose of preventing destruction of Low-K layer or crack in the solder bumps due to thermal stress.

It is indispensable for the underfill material to contain a large amount of filler in order to reduce the thermal expansion, whereas elevation of the content of filler increases the viscosity, consequently degrades readiness of filling of the underfill material into a gap between the semiconductor element and the substrate, and thereby considerably degrades the productivity.

For example, while elevation of the viscosity possibly induced by increase in the content of the filler may be suppressed by adopting a filler having a large particle size, this conversely induces sedimentation of the filler or degrades the readiness of filling-up of a narrow gap due to clogging of the filler. While many techniques have been proposed aiming at solving the degradation of the readiness of filling possibly induced by the increased content of filler (see Patent Documents 1 and 2, for example), none of them has been sufficient enough to solve the problem. Therefore, an epoch-making technique of enabling increase in the content of filler without impairing the readiness of filling-up of a narrow gap has strongly been desired.

### PRIOR ART DOCUMENTS

### Patent Documents

[Patent Document 1] Japanese Laid-Open Patent Publication No. 2005-119929
[Patent Document 2] Japanese Laid-Open Patent Publication No. 2003-137529

### DISCLOSURE OF THE INVENTION

It is therefore an object of the present invention to provide a liquid resin composition capable of densely containing a filler and of readily filling up a narrow gap in a flip-chip-bonded semiconductor device, and a highly-reliable semiconductor device using the same.

The object may be achieved by the present invention described in [1] to [11] below.

[1] A liquid resin composition which includes (A) an epoxy resin, (B) an epoxy resin curing agent, and (C) a filler, wherein content of the (C) filler is 60% by weight or more and 80% by weight or less of the whole liquid resin composition, and contact angle (8) of the liquid resin composition, measured at 110° C. in accordance with JIS R3257, is 30° or smaller.

[2] The liquid resin composition described in [1], which further includes (D) a Lewis base or a salt thereof.

[3] The liquid resin composition described in [2], wherein the (D) Lewis base or the salt thereof is 1,8-diazabicyclo[5.4.0]undecene-7 or 1,5-diazabicyclo[4.3.0]nonene-5, or a salt of these compounds.

[4] The liquid resin composition described in [2] or [3],

wherein content of the (D) Lewis base or the salt thereof is 0.005% by weight or more and 0.3% by weight or less of the whole liquid resin composition.

[5] The liquid resin composition described in any one of [1] to [4], which further includes (E) at least one species of compound selected from tetra-substituted phosphonium compound, phosphobetaine compound, adduct of phosphine compound and quinone compound, and adduct of phosphonium compound and silane compound.

[6] The liquid resin composition described in any one of [1] to [5], wherein the (C) filler has a maximum particle size of 25 μm or smaller, and an average particle size of 0.1 μm or larger and 10 μm or smaller.

[7] The liquid resin composition described in any one of [1] to [6], wherein content of the (C) filler is 70% by weight or more and 80% by weight or less of the whole liquid resin composition.

[8] The liquid resin composition described in any one of [2] to [7], wherein content of the (D) Lewis base or salt thereof relative to the content of the (C) filler ((D)/(C)) is 0.00006 or above and 0.005 or below.

[9] The liquid resin composition described in any one of [1] to [8], wherein the (B) epoxy resin curing agent is an amine curing agent or acid anhydride.

[10] The liquid resin composition described in any one of [1] to [9], wherein the (A) epoxy resin contains a structure having an aromatic ring coupled with a glycidyl structure or a glycidylamine structure.

[11] A semiconductor device manufactured by encapsulating a semiconductor element and a substrate using the liquid resin composition described in any one of [1] to [10].

According to the present invention, a liquid resin composition capable of densely containing a filler and of readily filling up a narrow gap in a flip-chip-bonded semiconductor device, and a highly-reliable semiconductor device using the same, may be obtained.

### BEST MODES FOR CARRYING OUT THE INVENTION

The liquid resin composition and semiconductor device of the present invention will be explained below.

The present invention relates to a liquid resin composition used for filling up a gap between a semiconductor element and a substrate in a flip-chip-bonded semiconductor device, which includes

(A) an epoxy resin, (B) an epoxy resin curing agent, and (C) a filler, wherein content of the (C) filler is 60% by weight or more and 80% by weight or less of the whole liquid resin composition, and contact angle (θ) of the liquid resin composition, measured at 110° C. in accordance with JIS R3257, is 30° or smaller.

The ingredients of the liquid resin composition of the present invention will be detailed. Note that the description below will be made merely for exemplary purposes, without limiting the present invention.

The (A) epoxy resin used in the present invention is not specifically restricted, so far as it has two or more epoxy groups in a single molecule. The epoxy resin may be exemplified by novolac-type epoxy resins such as phenol novolac-type epoxy resin, and cresol novolac-type epoxy resin; bisphenol-type epoxy resins such as bisphenol A-type epoxy resin, and bisphenol F-type epoxy resin; aromatic glycidylamine-type epoxy resins such as N,N-diglycidylaniline, N,N-diglycidyltoluidine, diaminodiphenylmethane-type glycidylamine, and aminophenol-type glycidylamine; epoxy resins such as hydroquinone-type epoxy resin, biphenyl-type epoxy resin, stilbene-type epoxy resin, triphenolmethane-type epoxy resin, triphenolpropane-type epoxy resin, alkyl-modified triphenolmethane-type epoxy resin, triazine kernel-containing epoxy resin, dicyclopentadiene-modified, phenol-type epoxy resin, naphthol-type epoxy resin, naphthalene-type epoxy resin, aralkyl-type epoxy resins such as phenylene- and/or biphenylene-skeleton-containing phenolaralkyl-type epoxy resin, and phenylene- and/or biphenylene-skeleton-containing naphtholaralkyl-type epoxy resin; and aliphatic epoxy resins such as alicyclic epoxy resins such as vinylcyclohexene dioxide, dicyclopentadien oxide, and alicyclic diepoxy adipate.

In the present invention, epoxy resins which contain an aromatic ring coupled with a glycidyl structure or glycidylamine structure are more preferable in view of improving the heat resistance, mechanical characteristics and moisture resistance, and aliphatic or alicyclic epoxy resin are more preferably controlled in the amount of use particularly in view of preventing reduction in the adhesiveness. They may be used independently, or in a combined manner contributed by two or more species.

Since the liquid resin composition of the present invention exists in a liquid form at room temperature, so that for the case where only a single species of the (A) epoxy resin is used as the (A) epoxy resin, such one species of the (A) epoxy resin exist in a liquid form, whereas for an alternative case where two or more species of the (A) epoxy resin are contained, a mixture of all of two or more species of such (A) epoxy resin exists in a liquid form at room temperature. Accordingly, for the case where the (A) epoxy resin is configured by a combination of two or more species of (A) epoxy resin, such (A) epoxy resin may be configured by a combination of epoxy resins, every one of which exists in a liquid form at room temperature; or may be configured by a combination of epoxy resin(s) which exists in a liquid form at room temperature and epoxy resin(s) which exists in a solid form at room temperature, so far as the mixture of them may exist in a liquid form at room temperature as a result of mixing, even if a part of which exists in a solid form at room temperature. For the case where the (A) epoxy resin is configured by a combination of two or more species of epoxy resin, it is not always necessary to prepare the liquid resin composition by mixing all epoxy resins to be used before being mixed with other ingredients, instead allowing separate mixing of the epoxy resins to be used, so as to finally prepare the liquid resin composition.

Note that “the (A) epoxy resin exists in a liquid form at room temperature” herein means that a mixture, obtained by mixing all epoxy resins to be used as the epoxy resin component (A), can exist in a liquid form at room temperature. Note that the room temperature in the present invention means 25° C., and also that a liquid form means that the resin composition exhibits fluidity.

While content of the (A) epoxy resin is not specifically restricted, it is preferably 5 to 30% by weight of the whole liquid resin composition of the present invention, and particularly preferably 5 to 20% by weight. By adjusting the content in the above-described ranges, the liquid resin composition may have excellent reactivity, heat resistance and mechanical strength of the composition, and fluidization characteristics in the process of filling.

The (B) epoxy resin curing agent used in the present invention is not specifically restricted in terms of structure, so far as it may cure the epoxy resin. Amine curing agent or acid anhydride is preferable as the (B) epoxy resin curing agent.

The amine curing agent may be exemplified by diethylenetriamine, triethylenetetramine, tetraethylenepentamine, trimethylhexamethylene diamine, 2-methyl pentamethylenediamine aliphatic polyamine; alicyclic polyamines such as m-xylene diamine, isophorone diamine, 1,3-bis(aminomethyl)cyclohexane, bis(4-aminocyclohexyl)methane, norbornenediamine, and 1,2-diaminocyclohexane; piperadine-type polyamines such as N-aminoethyl piperadine, and 1,4-bis(2-amino-2-methylpropyl)piperadine; and aromatic polyamines such as diaminodiphenylmethane, m-phenylenediamine, diaminodiphenyl sulfone, diethyltoluenediamine, trimethylenebis(4-aminobenzoate), and polytetramethylene oxide-di-p-aminobenzoate.

The acid anhydride may be exemplified by tetrahydroacid anhydride, hexahydrophthalic anhydride, methyltetrahydrophthalic anhydride, methylnadic anhydride, hydrogenated methylnadic anhydride, trialkyltetrahydrophthalic anhydride, methylcyclohexene tetracarboxylic dianhydride, phthalic anhydride, trimellitic anhydride, pyromeritic anhydride, bezophenone tetracarboxylic dianhydride, ethylene glycol bis(anhydro-trimellitate), glycerin bis(anhydro-trimellitate)monoacetate, and dodecenyl succinic anhydride.

Amine curing agent is particularly preferable, in view of improving the adhesiveness and moisture-resistant reliability. The amine curing agent may be used independently, or in a combined manner contributed by two or more species. In further consideration of application for encapsulation of semiconductor devices, aromatic polyamine-type curing agent is more preferable, in view of improving heat resistance, electrical characteristics, mechanical characteristics, adhesiveness and moisture resistance. In further consideration that the liquid resin composition of the present invention is used as the underfill material, those exist in a liquid form at room temperature (25° C.) are more preferable.

While content of the (B) epoxy resin curing agent is not specifically restricted, it is preferably 5 to 30% by weight of the whole liquid resin composition of the present invention, and particularly preferably 5 to 20% by weight. Excellent levels of the reactivity, mechanical characteristics and heat resistance of the composition and so forth may be achieved, by adjusting the content in the above-described ranges.

Ratio of active hydrogen equivalent of the (B) epoxy resin curing agent relative to epoxy equivalent of the (A) epoxy resin is preferably 0.6 to 1.4, and particularly preferably 0.7 to 1.3. Particularly excellent levels of the reactivity, and heat resistance of the composition may be achieved, by adjusting the ratio of active hydrogen equivalent of the (B) epoxy resin curing agent relative to epoxy equivalent of the (A) epoxy resin in the above-described ranges.

Since the (C) filler used in the present invention contributes to improve the mechanical strength such as fracture toughness, dimensional stability under heating and moisture resistance, the liquid resin composition may particularly improve the reliability of semiconductor device, by containing the (C) filler.

The (C) filler may be exemplified by silicates such as talc, calcined clay, uncalcined clay, mica, and glass; oxides such as titanium oxide, alumina, fused silica (fused spherical silica, fused ground silica), silica powders of synthetic silica and crystalline silica; carbonates such as calcium carbonate, magnesium carbonate, and hydrotulsite; hydroxides such as aluminum hydroxide, magnesium hydroxide, and calcium hydroxide; sulfates or sulfites such as barium sulfate, calcium sulfate, and calcium sulfite; borates such as zinc borate, barium metaborate, aluminum borate, calcium borate, and sodium borate; and nitrides such as aluminum nitride, boron nitride, and silicon nitride. The (C) filler may be used independently, or in a combined manner contributed by two or more species. Among them, fused silica, crystalline silica, and synthetic silica powder are preferable, in view of improving heat resistance, moisture resistance and strength of the resin composition.

While geometry of the (C) filler is not specifically restricted, sphere is preferable in view of viscosity and fluidity characteristics.

While maximum particle size and average particle size of the (C) filler are not specifically restricted, the maximum particle size is preferably 25 μm or smaller, and the average particle size is preferably 0.1 μm or larger and 10 μm or smaller. By adjusting the maximum particle size to the above-described upper limit value or smaller, an effect of suppressing the liquid resin composition from causing partial vacancy or filling failure when fluidized towards the semiconductor device, due to clogging of the filler, may be enhanced. On the other hand, by adjusting the average particle size to the above-described lower limit value or larger, viscosity of the liquid resin composition may appropriately be reduced, and thereby the readiness of filling may be improved.

The content of the (C) filler is preferably 60% by weight or more and 80% by weight or less of the whole liquid resin composition of the present invention, and more preferably 70% by weight or more and 80% by weight or less. By adjusting the content to the above-described lower limit value or above, an effect of improving reliability of the semiconductor device may be enhanced, whereas by adjusting it to the upper limit value or below, the liquid resin composition may be given a good balance of readiness of filling into narrow gap and reliability.

The liquid resin composition of the present invention has a contact angle (θ) of the liquid resin composition, measured at 110° C. in accordance with JIS R3257, of 30° or smaller. In the flip-chip-bonded semiconductor device, encapsulation resin is generally filled according to capillary effect. The present inventors then paid special attention to the contact angle at high temperatures under which the liquid resin composition is actually used for encapsulation of the flip-chip-bonded semiconductor device, and developed a liquid resin composition capable of inducing capillary effect as a result of reduction in the contact angle at high temperatures, and of improving readiness of filling up a narrow gap with the liquid resin composition, particularly even if a large amount of filler was contained therein.

The contact angle (θ) of the liquid resin composition of the present invention is preferably 0° or larger and 30° or smaller. By adjusting the contact angle at 110° C. to 30° or smaller, the liquid resin composition may be suppressed from being degraded in wetting performance in the process of encapsulation, and thereby the readiness of filling up a narrow gap may be improved.

The contact angle (θ) at 110° C. of the liquid encapsulation resin composition of the present invention was measured by the θ/2 method (liquid droplet method) in accordance with JIS R3257, by which contact angle observed on a slide glass (S1111, from Matsunami Glass Ind., Ltd.) was determined.

The liquid resin composition of the present invention preferably contains the (D) Lewis base or salt thereof in view of more readily reducing the contact angle (θ).

The (D) Lewis base or salt thereof may be exemplified by amine compounds such as 1,8-diazabicyclo[5.4.0]undecene-7,1,5-diazabicyclo[4.3.0]nonene-5,1,4-diazabicyclo[2.2.2]octane, imidazoles, diethylamine, triethylenediamine, benzyl dimethylamine, 2-dimethylaminomethylphenol, 2,4,6-tris(dimethylaminomethyl)phenol, and salts of these compounds; and phosphine compounds such as triphenylphosphine, phenylphosphine, and diphenylphosphine. Among them, tertiary amine compounds such as benzyl dimethylamine, 2-dimethylaminomethylphenol, and 2,4,6-tris(dimethylaminomethyl)phenol; imidazoles; and 1,8-diazabicyclo[5.4.0]undecene-7,1,5-diazabicyclo[4.3.0]nonene-5, and 1,4-diazabicyclo[2.2.2]octane, and salts of these compounds. In particular, from the viewpoint of reducing the contact angle (θ), 1,8-diazabicyclo[5.4.0]undecene-7, and 1,5-diazabicyclo[4.3.0]nonene-5 or salts of these compounds are preferable. Salts of the (D) Lewis base may be exemplified by phenol salt of Lewis base, and more specifically, phenol salt of 1,8-diazabicyclo[5.4.0]undecene-7.

While content of the (D) Lewis base and salt thereof is not specifically restricted, it is preferably 0.005% by weight or more and 0.3% by weight or less of the whole liquid resin composition, particularly preferably 0.01% by weight or more and 0.2% by weight or less, and still more preferably 0.02% by weight or more and 0.1% by weight or less. The content lower than the above-described lower limit value may result in insufficient effect of reducing the contact angle (θ) at 110° C., and degradation of readiness of filling of narrow gap. On the other hand, the content higher than the above-described value may induce increase in the viscosity of the liquid resin composition, and thereby the readiness of filling may be degraded.

While the (D) Lewis base or salt thereof is not specifically restricted, it is preferably premixed with the (A) epoxy resin and/or the (B) epoxy resin curing agent, before the liquid resin composition of the present invention is prepared. By the procedure, dispersibility of the (D) Lewis base or salt thereof into the (A) epoxy resin and/or (B) epoxy resin curing agent may be improved, and in particular an effect of reducing the contact angle (θ) at 110° C. may be enhanced. In particular, the procedure may very effectively enhance the effect of improving readiness of filling-up of the narrow gap, when a large amount of the (C) filler is contained. In short, by improving the dispersibility into the (A) epoxy resin and/or (B) epoxy resin curing agent, the wetting performance with respect to the semiconductor element and the substrate of the flip-chip-bonded semiconductor device may be improved, and thereby the readiness of filling-up of the narrow gap may further be improved.

“Premixing” herein means preliminary mixing under stirring at room temperature, where there is no upper limit of time of mixing under stirring. In view of allowing uniform dispersion of the (D) Lewis base or salt thereof into the (A) epoxy resin and/or (B) epoxy resin curing agent, the mixture is preferably mixed under stirring for one hour or longer.

Similarly to the (D) Lewis base or salt thereof, in view of facilitating reduction in the contact angle (θ) at 110° C., the liquid resin composition of the present invention preferably contains, as compound (E), at least one species selected from tetra-substituted phosphonium compound, phosphobetaine compound, adduct of phosphine compound and quinone compound, and adduct of phosphonium compound and silane compound.

Tetra-substituted phosphonium compound used as the compound (E) may be exemplified by compounds represented by formula (1) below.

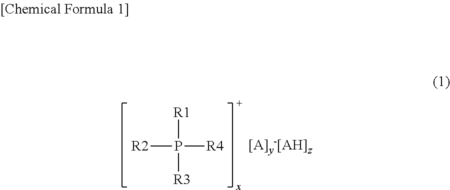

(In the formula (1), P represents a phosphorus atom. Each of R1, R2, R3 and R4 represents an aromatic group or alkyl group. “A” represents an anion of aromatic compound having, on the aromatic ring thereof, at least one functional group selected from hydroxyl group, carboxyl group, and thiol group. AH represents an aromatic compound having, on the aromatic ring thereof, at least one functional group selected from hydroxyl group, carboxyl group, and thiol group. Each of x and y represents an integer from 1 to 3, z represents an integer from 0 to 3, wherein x=y holds.)

In the formula (1), each of R1, R2, R3 and R4 preferably represents an aromatic group or alkyl group, having 1 to 10 carbon atoms. In view of enhancing an effect of reducing the contact angle (θ) at 110° C., a preferable compound is such that each of R1, R2, R3 and R4 bound to phosphorus atom represents a phenyl group, AH represents a compound having a hydroxyl group bound to an aromatic ring, or a phenol compound, and “A” represents an anion of such phenol compound.

Phosphobetaine compound used as the compound (E) may be exemplified by compounds typically represented by formula (2) below.

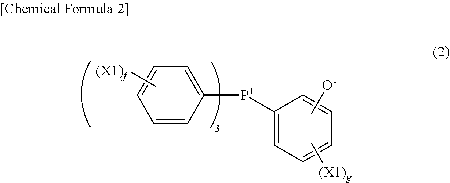

(In the formula (2), P represents a phosphorus atom. X1 represents an alkyl group having 1 to 3 carbon atoms, and Y1 represents a hydroxyl group. f represents an integer from 0 to 5, and g represents an integer from 0 to 3.)

Adduct of phosphine compound and quinone compound, used as the compound (E), may be exemplified by compounds represented by formula (3) below.

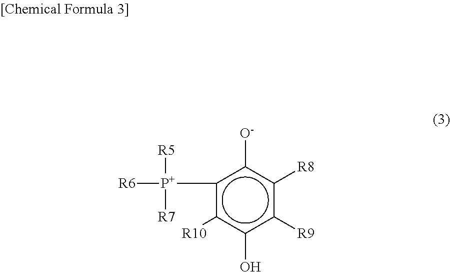

(In the formula (3), P represents a phosphorus atom. Each of R5, R6 and R7 represents an alkyl group having 1 to 12 carbon atoms or an aryl group having 6 to 12 carbon atoms, which may be same with, or different from each other. Each of R8, R9 and R10 represents a hydrogen atom or hydrocarbon group having 1 to 12 carbon atoms, which may be same with, or different from each other, and R8 and R9 may bind with each other to give a cyclic structure.)

Phosphine compound composing the adduct of phosphine compound and quinone compound, used as the compound (E), may preferably be those having aromatic rings which are unsubstituted or substituted by substituent such as alkyl groups, alkoxyl groups and so forth, and may be exemplified by triphenylphosphine, tris(alkylphenyl)phosphine, tris(alkoxyphenyl)phosphine, trinaphthylphosphine, and tris(benzyl)phosphine. The substituents such as alkyl group, alkoxyl group and so forth may be exemplified by those having 1 to 6 carbon atoms. Triphenylphosphine is preferable from the viewpoint of availability.

Quinone compound composing the adduct of phosphine compound and quinone compound, used as the compound (E), may be exemplified by o-benzoquinone, p-benzoquinone, and anthraquinones, among which p-benzoquinone is preferable from the viewpoint of shelf stability.

Adduct of phosphonium compound and silane compound, used as the compound (E), may be exemplified by compounds represented by formula (4) below.

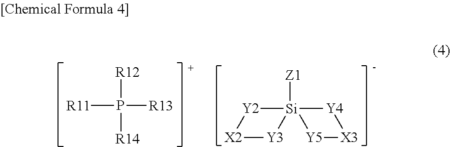

(In the formula (4), P represents a phosphorus atom, and Si represents a silicon atom. Each of R11, R12, R13 and R14 independently represents an organic group having an aromatic ring or heteroring, or having an aliphatic group, which may be same with, or different from each other. X2 in the formula represents an organic group bound to groups Y2 and Y3. X3 in the formula represents an organic group bound to groups Y4 and Y5. Each of Y2 and Y3 represents a group ascribable to a proton-donating group remained after releasing protons, and Y2 and Y3 in the same molecule bound to the silicon atom to form a chelate structure. Each of Y4 and Y5 represents a group ascribable to a proton-donating group remained after releasing protons, and Y4 and Y5 in the same molecule bound to the silicon group to form a chelate structure. X2 and X3 may be same with, or different from each other, and Y2, Y3, Y4, and Y5 may be same with, or different from each other. Z1 represents an organic group having an aromatic ring or heteroring, or an aliphatic group.)

In the formula (4), each of R11, R12, R13 and R14 may typically be exemplified by a phenyl group, methylphenyl group, methoxyphenyl group, hydroxyphenyl group, naphthyl group, hydroxynaphthyl group, benzyl group, methyl group, ethyl group, n-butyl group, n-octyl group and cyclohexyl group. Among them, substituted aromatic groups having substituents and unsubstituted aromatic group are preferable, which are exemplified by phenyl group, methylphenyl group, methoxyphenyl group, hydroxyphenyl group, and hydroxynaphthyl group.

X2 in the formula (4) represents an organic group bound to Y2 and Y3. Similarly, X3 represents an organic group bound to groups Y4 and Y5. Each of Y2 and Y3 represents a group ascribable to a proton-donating group remained after releasing protons, and Y2 and Y3 in the same molecule bound to the silicon atom to form a chelate structure. Similarly, each of Y4 and Y5 represents a group ascribable to a proton-donating group remained after releasing protons, and Y4 and Y5 in the same molecule bound to the silicon atom to form a chelate structure. X2 and X3 may be same with, or different from each other, and Y2, Y3, Y4, and Y5 may be same with, or different from each other.

Groups represented by —Y2-X2-Y3- and —Y4-X3-Y5- in the formula (4) are configured by groups ascribable to proton donor remained after releasing protons. This sort of proton donor, or compound before releasing protons, may be exemplified by catechol, pyrogallol, 1,2-dihydroxynaphthalene, 2,3-dihydroxynaphthalene, 2,2′-biphenol, 1,1′-Bi-2-naphthol, salicylic acid, 1-hydroxy-2-naphthoic acid, 3-hydroxy-2-naphthoic acid, chloranilic acid, tannic acid, 2-hydroxybenzyl alcohol, 1,2-cyclohexanediol, 1,2-propanediol and glycerin. Among them, catechol, 1,2-dihydroxynaphthalene, and 2,3-dihydroxynaphthalene are more preferable.

Z1 in the formula (4) represents an organic group having an aromatic ring or heteroring, or an aliphatic group, and may specifically be exemplified by aliphatic hydrocarbon groups such as methyl group, ethyl group, propyl group, butyl group, hexyl group and octyl group; aromatic hydrocarbon groups such as phenyl group, benzyl group, naphthyl group and biphenyl group; and reactive substituents such as glycidyloxypropyl group, mercaptopropyl group, aminopropyl group and vinyl group. Among them, methyl group, ethyl group, phenyl group, naphthyl group and biphenyl group are more preferable from the viewpoint of heat stability.

For the case where the liquid resin composition of the present invention contains the (D) Lewis base or salt thereof, content of the (D) Lewis base or salt thereof relative to content of the (C) filler ((D)/(C)) is preferably 0.00006 or above and 0.005 or below, and particularly preferably 0.0001 or above and 0.0035 or below. By the adjustment, an effect of reducing the contact angle (θ) at 110° C. may be enhanced.

For the case where the liquid resin composition of the present invention contains, as the compound (E), at least one species selected from tetra-substituted phosphonium compound, phosphobetaine compound, adduct of phosphine compound and quinone compound, and adduct of phosphonium compound and silane compound, the content of the compound (E) relative to content of the (C) filler (weight ratio of (E)/(C)) is preferably 0.00006 or above and 0.005 or below, and particularly preferably 0.0001 or above and 0.0035 or below. By the adjustment, an effect of reducing the contact angle (θ) at 110° C. may be enhanced.

The liquid resin composition of the present invention may be added with additives such as diluting agent, pigment, flame retarder, leveling agent and defoaming agent depending on need, besides the above-described (A) epoxy resin, (B) epoxy resin curing agent, and (C) filler.

The liquid resin composition of the present invention may be manufactured by dispersing and kneading the above-described ingredients and additives, using a planetary mixer, three-roll, two-heating-roll, mincing machine or the like, and by subjecting the dispersion to defoaming in vacuo.

The semiconductor device of the present invention is manufactured by using the liquid resin composition of the present invention.

More specifically, flip-chip-type semiconductor device may be exemplified. As for the flip-chip-type semiconductor device, a semiconductor element having solder electrodes provided thereto is bonded to a substrate, and a gap between the semiconductor element and the substrate is filled up. In this case, it is general to form a solder resist layer on the substrate selectively in the area thereof remained unused for bonding with the solder electrodes, so as to prevent overflow of solder.

Next, the gap between the semiconductor element and the substrate is filled up with the liquid resin composition of the present invention. Method of filling generally relies upon use of capillary effect. More specifically, possible methods include a method of applying the liquid resin composition of the present invention to one edge of the semiconductor element, and then allowing the composition to flow into the gap between the semiconductor element and the substrate based on capillary effect; a method of applying the liquid resin composition to two edges of the semiconductor element, and then allowing the composition to flow into the gap between the semiconductor element and the substrate based on capillary effect; and a method of applying the liquid resin composition around the edges of the semiconductor element having a through-hole preliminarily bored at the center thereof, and then allowing the composition to flow into the gap between the semiconductor element and the substrate based on capillary effect. Rather than applying the whole amount of composition at a time, the coating process may be divided into two processes. Potting, printing and so forth may also be adoptable.

Next, the thus-filled liquid resin composition of the present invention is allowed to cure. While conditions for curing are not specifically restricted, the curing may be proceeded under heating typically in the temperature range from 100° C. to 170° C., for 1 to 12 hours. Still alternatively, the curing under heating may be proceeded while step-wisely varying the temperature, such as heating the resin at 100° C. for one hour, followed by heating at 150° C. for two hours.

In this way, the semiconductor device in which the gap between the semiconductor element and the substrate is filled up with the liquid resin composition of the present invention may be obtained.

This sort of semiconductor devices may be exemplified by flip-chip-bonded semiconductor device, cavity-down-type BGA (Ball Grid Array), POP (Package on Package)-type BGA (Ball Grid Array), TAB (Tape Automated Bonding)-type BGA (Ball Grid Array), and CSP (Chip Scale Package).

### EXAMPLES

The present invention will be detailed referring to Examples and Comparative Examples, without restricting the present invention.

### Example 1

Using a three-roll mill, 21.0% by weight of (A) epoxy resin (EXA-830LVP from DIC Corpoartion), 7.9% by weight of amine curing agent (Kayahard AA from Nippon Kayaku Co., Ltd.) as the (B) epoxy resin curing agent, 71% by weight of (C) filler (Admafine SO-E3 from Admatechs Co., Ltd. (maximum particle size=5 μm, average particle size 1=μm), and 0.1% by weight of 1,8-diazabicyclo[5.4.0]undecene-7 (DBU) as the (D) Lewis base were kneaded and dispersed, and the dispersion was then defoamed in vacuo to thereby obtain a liquid resin composition. The (A) epoxy resin and DBU were preliminarily mixed under stirring at room temperature for one hour, before use.

### Example 2

A liquid resin composition was prepared similarly as described in Example 1, except that the content of DBU was decreased, and thereby the contents as a whole were adjusted as described below.

Using a three-roll mill, 21.1% by weight of (A) epoxy resin (EXA-830LVP, from DIC Corporation), 7.9% by weight of amine curing agent (Kayahard AA, from Nippon Kayaku Co., Ltd.) as the (B) epoxy resin curing agent, 70.994% by weight of (C) filler (Admafine SO-E3, from Admatechs Co., Ltd., maximum particle size=5 μm, average particle size=1 μm), and 0.006% by weight of 1,8-diazabicyclo[5.4.0]undecene-7 (DBU) as the (D) Lewis base were kneaded and dispersed, and the dispersion was then defoamed in vacuo to thereby obtain a liquid resin composition. The (A) epoxy resin and DBU were preliminarily mixed under stirring at room temperature for one hour, before use.

### Example 3

A liquid resin composition was prepared similarly as described in Example 1, except that the content of DBU was increased, and thereby the contents as a whole were adjusted as described below.

Using a three-roll mill, 20.85% by weight of (A) epoxy resin (EXA-830LVP, from DIC Corporation), 7.9% by weight of amine curing agent (Kayahard AA, from Nippon Kayaku Co., Ltd.) as the (B) epoxy resin curing agent, 71% by weight of (C) filler (Admafine SO-E3, from Admatechs Co., Ltd., maximum particle size=5 μm, average particle size=1 μm), and 0.25% by weight of 1,8-diazabicyclo[5.4.0]undecene-7 (DBU) as the (D) Lewis base were kneaded and dispersed, and the dispersion was then defoamed in vacuo to thereby obtain a liquid resin composition. The (A) epoxy resin and DBU were preliminarily mixed under stirring at room temperature for one hour, before use.

### Example 4

A liquid resin composition was prepared similarly as described in Example 1, except that the content of (C) filler was increased, and thereby the contents as a whole were adjusted as described below.

Using a three-roll mill, 19.3% by weight of (A) epoxy resin (EXA-830LVP, from DIC Corporation), 7.5% by weight of amine curing agent (Kayahard AA, from Nippon Kayaku Co., Ltd.) as the (B) epoxy resin curing agent, 73.1% by weight of (C) filler (Admafine SO-E3, from Admatechs Co., Ltd., maximum particle size=5 μm, average particle size=1 μm), and 0.1% by weight of 1,8-diazabicyclo[5.4.0]undecene-7 (DBU) as the (D) Lewis base were kneaded and dispersed, and the dispersion was then defoamed in vacuo to thereby obtain a liquid resin composition. The (B) epoxy resin curing agent and DBU were preliminarily mixed under stirring at room temperature for one hour, before use.

### Example 5

A liquid resin composition was prepared similarly as described in Example 1, except that DBU-phenol salt (U-CAT SAl, from San-Apro, Ltd.) was used in place of DBU. The (A) epoxy resin and DBU-phenol salt were preliminarily mixed under stirring at room temperature for one hour, before use.

### Example 6

A liquid resin composition was prepared similarly as described in Example 1, except that tetra-substituted phosphonium compound represented by formula (5) below was used as the compound (E), in place of DBU. The (A) epoxy resin and tetra-substituted phosphonium compound used as the compound (E) represented by the formula (5) below were not preliminarily mixed at room temperature.

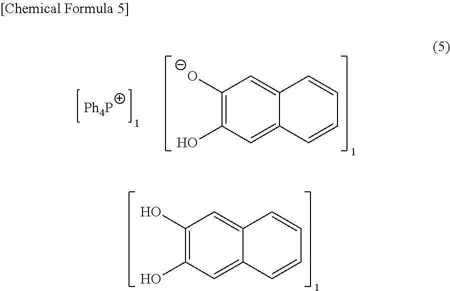

### Example 7

A liquid resin composition was prepared similarly as described in Example 1, except that tetra-substituted phosphobetaine compound represented by formula (6) below was used as the compound (E), in place of DBU. The (A) epoxy resin and tetra-substituted phosphobetaine compound used as the compound (E) represented by the formula (6) below were not preliminarily mixed at room temperature.

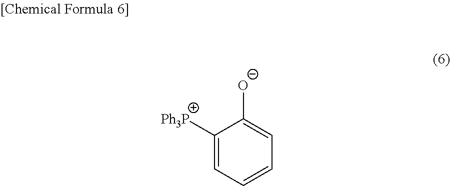

### Example 8

Using a three-roll mill, 14.1% by weight of (A) epoxy resin (EXA-830LVP, from DIC Corporation), 14.4% by weight of acid anhydride curing agent (HN-2200R, from Hitachi Chemical Co., Ltd.) as the (B) epoxy resin curing agent, 71% by weight of (C) filler (Admafine SO-E3, from Admatechs Co., Ltd., maximum particle size=5 μm, average particle size=1 μm), and 0.5% by weight of tetra-substituted phosphonium compound represented by formula (7) below used as the compound (E) were kneaded and dispersed, and the dispersion was then defoamed in vacuo to thereby obtain a liquid resin composition. The (A) epoxy resin and tetra-substituted phosphonium compound represented by the formula (7) used as the compound (E) were not preliminarily mixed at room temperature.

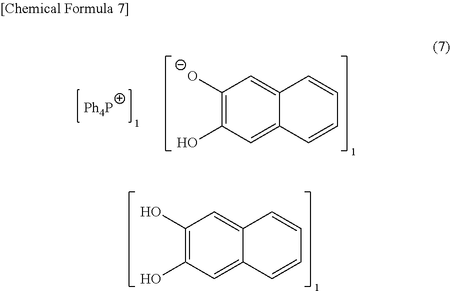

### Example 9

Using a three-roll mill, 21.1% by weight of (A) epoxy resin (EXA-830LVP, from DIC Corporation), 7.9% by weight of amine curing agent (Kayahard AA from Nippon Kayaku Co., Ltd.) as the (B) epoxy resin curing agent, 70.9% by weight of (C) filler (Admafine SO-E3, from Admatechs Co., Ltd., maximum particle size=5 μm, average particle size=1 μm), and 0.1% by weight of 1,8-diazabicyclo[5.4.0]undecene-7 (DBU) used as the (D) Lewis base were kneaded and dispersed, and the dispersion was then defoamed in vacuo to thereby obtain a liquid encapsulation resin composition. The (A) epoxy resin and DBU were preliminarily mixed under stirring at room temperature for four hours.

### Example 10

Using a three-roll mill, 21.1% by weight of (A) epoxy resin (EXA-830LVP, from DIC Corporation), 7.9% by weight of amine curing agent (Kayahard AA from Nippon Kayaku Co., Ltd.) as the (B) epoxy resin curing agent, 70.9% by weight of (C) filler (Admafine SO-E3, from Admatechs Co., Ltd., maximum particle size=5 μm, average particle size=1 μm), and 0.1% by weight of 1,8-diazabicyclo[5.4.0]undecene-7 (DBU) used as the (D) Lewis base were kneaded and dispersed, and the dispersion was then defoamed in vacuo to thereby obtain a liquid encapsulation resin composition. The (A) epoxy resin and DBU were preliminarily mixed under stirring at room temperature for 12 hours.

### Example 11

Using a three-roll mill, 21.1% by weight of (A) epoxy resin (EXA-830LVP, from DIC Corporation), 7.9% by weight of amine curing agent (Kayahard AA from Nippon Kayaku Co., Ltd.) as the (B) epoxy resin curing agent, 70.9% by weight of (C) filler (Admafine SO-E3, from Admatechs Co., Ltd., maximum particle size=5 μm, average particle size=1 μm), and 0.1% by weight of 1,8-diazabicyclo[5.4.0]undecene-7 (DBU) used as the (D) Lewis base were kneaded and dispersed, and the dispersion was then defoamed in vacuo to thereby obtain a liquid encapsulation resin composition. The (B) epoxy resin curing agent and DBU were preliminarily mixed under stirring at room temperature for 12 hours.

### Comparative Example 1

A liquid resin composition was prepared similarly as described in Example 1, except that none of the (D) Lewis base and salt thereof, and (E) tetra-substituted phosphonium compound, phosphobetaine compound, adduct of phosphine compound and quinone compound, and phosphonium compound and silane compound were used, and that the contents as a whole were adjusted as described below.

Using a three-roll mill, 25.1% by weight of (A) epoxy resin (EXA-830LVP, from DIC Corporation), 9.9% by weight of amine curing agent (Kayahard AA from Nippon Kayaku Co., Ltd.) as the (B) epoxy resin curing agent, and 65% by weight of (C) filler (Admafine SO-E3, from Admatechs Co., Ltd., maximum particle size=5 μm, average particle size=1 μm) were kneaded and dispersed, and the dispersion was then defoamed in vacuo to thereby obtain a liquid resin composition.

### Comparative Example 2

A liquid resin composition was prepared similarly as described in Comparative Example 1, except that content of the (C) filler was increased, and that the contents as a whole were adjusted as described below.

Using a three-roll mill, 21.5% by weight of (A) epoxy resin (EXA-830LVP, from DIC Corporation), 8.5% by weight of amine curing agent (Kayahard AA from Nippon Kayaku Co., Ltd.) as the (B) epoxy resin curing agent, and 70% by weight of (C) filler (Admafine SO-E3, from Admatechs Co., Ltd., maximum particle size=5 μm, average particle size=1 μm) were kneaded and dispersed, and the dispersion was then defoamed in vacuo to thereby obtain a liquid resin composition.

### [Items of Evaluation]

The thus-obtained liquid resin compositions were evaluated with respect to the items below. Results were shown in Tables 1 and 2.

### 1. Fluidity

A glass plate (upper) and a glass plate (lower), each having a size of 18 mm×18 mm, were bonded while keeping a 70±10 μm gap in between, to thereby fabricate a glass cell having a gapped parallel surfaces. The glass cell was placed on a hot plate, and allowed to stand for 5 minutes while adjusting temperature of the top surface of the glass plate (upper) to 110±1° C. An appropriate amount of the liquid resin composition was coated on one edge of the glass cell, and time taken by the liquid resin to flow over 18 mm (fluidization time) was measured. Explanation of the marks are as follows:

AA: those characterized by fluidization time of 100 seconds or longer and shorter than 150 seconds;

BB: those characterized by fluidization time of 150 seconds or longer and shorter than 250 seconds;

CC: those characterized by fluidization time of 250 seconds or longer and shorter than 300 seconds; and

DD: those characterized by fluidization time of 300 seconds or longer.

### 2. Contact Angle

Contact angle (θ) of the liquid resin composition on the slide glass (S1111, from Matsunami Glass Ind., Ltd.) was measured.

The contact angle was measured using a CA-V-type automatic contact angle meter from Kyowa Interface Science Co., Ltd., in an atmosphere of measurement at 110° C., based on the 0/2 method (liquid droplet method) in accordance with JIS R3257. Smaller contact angle means better wetting performance.

### 3. Evaluation of Semiconductor Device

Semiconductor devices were manufactured by allowing the liquid resin compositions obtained in Examples 1 to 11 and Comparative Examples 1, 2 to flow into a gap between a circuit substrate and a semiconductor chip, bonded with each other through solder bumps, so as to fill up the gap, and were subjected to resin filling test, reflow test and temperature cycle test. Constituents of the semiconductor devices used for the tests and evaluation were the followings.

The semiconductor chip used herein was prepared by forming a polyimide film for semiconductor circuit protection on a PHASE-2 TEG wafer from Hitachi ULSI Systems Co., Ltd., placing thereon solder bumps composed of a Sn/Ag/Cu lead-free solder, and by dicing the wafer to produce 15 mm×15 mm×0.8 mm (thickness) chips.

The circuit substrate was prepared by using, as a base, a 0.8-mm-thick, FR-5-level glass epoxy substrate from Sumitomo Bakelite Co., Ltd., coating on both surfaces thereof solder resist PSR4000/AUS308 from Taiyo Ink Mfg. Co., Ltd., and forming gold-plated pads on one surface thereof corresponding to layout of the above-described solder bumps. The circuit substrate was diced to produce 50 mm×50 mm substrates, and used.

Flux used herein for bonding was TSF-6502 (rodin flux, from Kester).

In the process of assembly of the semiconductor devices, the flux was uniformly coated to as thick as 50 μm over a sufficiently smooth metal or glass plate using a doctor blade, and a semiconductor chip having the solder bumps formed thereon was brought into light contact, on the side thereof having the solder bumps arranged thereon, with the flux film using a flip-chip bonder, and then brought apart to thereby transfer the flux onto the solder bumps. The semiconductor chip was then pressed onto the circuit substrate. Next, the product was heated in an IR reflow furnace so as to fuse the solder bumps to thereby ensure bonding. After the bonding under fusion, the product was cleaned using a cleaning solution. In the process of filling and encapsulation using the liquid resin composition, the thus-obtained semiconductor device was heated on a hot plate at 110° C., the thus-prepared liquid resin composition was coated on one edge of the semiconductor chip so as to fill the gap, and the liquid resin composition was cured under heating in an oven at 150° C. for 120 minutes. The semiconductor devices to be tested and evaluated were thus obtained.

### 3.1 Filling Test

In the filling test of the liquid resin composition, the thus-manufactured semiconductor devices after cured were confirmed with respect to the readiness of filling, using an ultrasonic flaw detector.

good: those having the gap thoroughly filled up with the liquid resin composition; and

not filled: those having the gap which could not thoroughly be filled up with the liquid resin composition.

### 3.2 Reflow Test

In the reflow test, the semiconductor devices were allowed to absorb moisture at JEDEC level 3 (30° C., 60% relative humidity, for 168 hours), and subjected to IR reflow (peak temperature=260° C.) three times, and then confirmed with respect to occurrence of separation of the liquid resin composition inside the semiconductor devices using a ultrasonic flaw detector, and further observed under an optical microscope with respect to crack on the surfaces of the liquid resin compositions on the side faces of the semiconductor chips.

### 3.3 Temperature Cycle Test

In the temperature cycle test, the semiconductor devices after being subjected to the above-described reflow test were put into a cold-hot cycle between −55° C./30 minutes and 125° C./30 minutes, confirmed for every 250 cycles with respect to occurrence of separation at the interfaces between the semiconductor chips and the liquid resin compositions inside the semiconductor devices, using a ultrasonic flaw detector, and further observed under an optical microscope with respect to crack on the surfaces of the liquid resin compositions on the side faces of the semiconductor chips. The temperature cycle test was repeated finally up to 1000 cycles.

Results were shown in Tables 1 and 2.

The reflow test and the temperature cycle test were not carried out for Comparative Examples 1 and 2, since the obtained semiconductor devices were found to show poor levels of readiness of filling.

The semiconductor devices of Examples 1 to 11 were found to operate without problem.

TABLE 1

| | | | Example 1 | Example 2 | Example 3 | Example 4 | Example 5 | Example 6 | Example 7 |
|---|---|---|---|---|---|---|---|---|---|
| Fluidity | | | AA | BB | BB | BB | AA | AA | AA |
| Contact | deg | Slide glass | 23 | 27 | 22 | 26 | 22 | 20 | 24 |
| angle (Θ) | | | | | | | | | |

| | | | | | | | | |
|---|---|---|---|---|---|---|---|---|
| Evaluation of | Readiness of | good | good | good | good | good | good | good |
| semiconductor | filling | | | | | | | |
| device | Reflow test | no crack, | no crack, | no crack, | no crack, | no crack, | no crack, | no crack, |
| | | no separation | no | no | no | no | no | no |
| | | | separation | separation | separation | separation | separation | separation |
| | Temperature | no crack, | no crack, | no crack, | no crack, | no crack, | no crack, | no crack, |
| | cycle test | no separation | no | no | no | no | no | no |
| | | | separation | separation | separation | separation | separation | separation |

TABLE 2

| | | | | | | | Comparative | Comparative |
|---|---|---|---|---|---|---|---|---|
| | | | Example 8 | Example 9 | Example 10 | Example 11 | Example 1 | Example 2 |
| Fluidity | | | AA | AA | AA | AA | CC | DD |
| Contact | deg | Slide glass | 18 | 22 | 23 | 22 | 40 | 48 |
| angle | | | | | | | | |
| (Θ) | | | | | | | | |

| | | | | | | | |
|---|---|---|---|---|---|---|---|
| Evaluation of | Readiness of | good | good | good | good | not filled | not filled |
| semiconductor | filling | | | | | | |
| device | Reflow test | no crack, | no crack, | no crack, | no crack, | | |
| | | no | no | no | no | | |
| | | separation | separation | separation | separation | | |
| | Temperature | no crack, | no crack, | no crack, | no crack, | | |
| | cycle test | no | no | no | no | | |
| | | separation | separation | separation | separation | | |

This application claims priority right based on Japanese Patent Application No. 2008-330760 filed on Dec. 25, 2008, the entire content of which is incorporated hereinto by reference.

1. A liquid resin composition comprising:
(A) an epoxy resin;
(B) an epoxy resin curing agent; and
(C) a filler,
content of said (C) filler being 60% by weight or more and 80% by weight or less of said whole liquid resin composition, and
contact angle (θ) of said liquid resin composition, measured at 110° C. in accordance with JIS R3257, being 30° or smaller.

2. The liquid resin composition as claimed in claim 1, further comprising:
(D) a Lewis base or a salt thereof.

3. The liquid resin composition as claimed in claim 2,
wherein said (D) Lewis base or said salt thereof is 1,8-diazabicyclo[5.4.0]undecene-7 or 1,5-diazabicyclo[4.3.0]nonene-5, or a salt of these compounds.

4. The liquid resin composition as claimed in claim 2,
wherein content of said (D) Lewis base or salt thereof is 0.005% by weight or more and 0.3% by weight or less of said whole liquid resin composition.

5. The liquid resin composition as claimed in claim 1, further comprising:
(E) at least one species of compound selected from tetra-substituted phosphonium compound, phosphobetaine compound, adduct of phosphine compound and quinone compound, and adduct of phosphonium compound and silane compound.

6. The liquid resin composition as claimed in claim 1,
wherein said (C) filler has a maximum particle size of 25 μm or smaller, and an average particle size of 0.1 μm or larger and 10 μm or smaller.

7. The liquid resin composition as claimed in claim 1,
wherein content of said (C) filler is 70% by weight or more and 80% by weight or less of said whole liquid resin composition.

8. The liquid resin composition as claimed in claim 2,
wherein content of said (D) Lewis base or salt thereof relative to the content of said (C) filler ((D)/(C)) is 0.00006 or above and 0.005 or below.

9. The liquid resin composition as claimed in claim 1,
wherein said (B) epoxy resin curing agent is an amine curing agent or acid anhydride.

10. The liquid resin composition as claimed in claim 1,
wherein said (A) epoxy resin contains a structure having an aromatic ring coupled with a glycidyl structure or a glycidylamine structure.

11. A semiconductor device manufactured by encapsulating a semiconductor element and a substrate using the liquid resin composition described in claim 1.
